(19) United States
(12) Patent Application Publication
(10) Pub. No.: US 2017/0226626 A1
(43) Pub. Date: Aug. 10, 2017

(54) CRUCIBLE REPLACING APPARATUS

(71) Applicant: BOE TECHNOLOGY GROUP CO., LTD., Beijing (CN)

(72) Inventor: Xindi ZHANG, Beijing (CN)

(21) Appl. No.: 15/110,852

(22) PCT Filed: Jan. 8, 2016
(86) PCT No.: PCT/CN2016/070448

§ 371 Date: Jul. 11, 2016

(30) Foreign Application Priority Data
Aug. 7, 2015 (CN) 201510484948.3

(51) Int. Cl. C23C 14/24

(52) U.S. Cl. CPC C23C 14/243

(57) ABSTRACT

The present invention relates to the technical field of displays, in particular to a crucible replacing apparatus. The crucible replacing apparatus comprises: a base, a first mechanical arm and a second mechanical arm; the first mechanical arm and the second mechanical arm are disposed on the base respectively, and perform the actions of turning, rising and falling along with the base; one end of the first mechanical arm is for catching a crucible to be replaced; and one end of the second mechanical arm is for carrying and placing a spare crucible, thus achieving the replacement of the crucible in the evaporation source without opening the chamber and cooling to the room temperature.

### TECHNICAL FIELD

The present invention relates to the technical field of displays, in particular to a crucible replacing apparatus.

### BACKGROUND ART

Currently, the vessel used for a point-source evaporator is a crucible from which the material is evaporated. Generally, in the same evaporation chamber there are a varied number of evaporation sources and different materials are evaporated from the evaporation sources. The materials in different evaporation sources are consumed in different rates due to the difference in the thickness and doping ratio of each layer in each device. Therefore, the material with the largest consumption decides the time to open the chamber for adding materials. Generally, when adding materials, the material with the largest consumption is added the most, while the other materials are added less proportionally, which is equivalent to wasting the capacities of the crucibles and increasing the frequency of opening the chamber for adding materials, thus reducing the evaporation efficiency. If the addition amount of the material with the largest consumption is increased, the frequency of opening the chamber for adding materials may be reduced. With respect to such a situation, the existing solution usually increases the capacity of the crucible for the material (renovating the evaporation source and using a crucible with a larger capacity). The specific process is: cooling (cooling to the room temperature)—opening the chamber—adding material—vacuumizing—heating up, which requires a very long time, usually more than 4 hours, thus influencing the service efficiency of the apparatus, and definitely causing severe production loss, especially for a production line.

### SUMMARY

### (1) Technical Problem to be Solved

The technical problem to be solved by the present invention is: how to replace a crucible in an evaporation source without opening the chamber and cooling to the room temperature.

### (2) Technical Solution

In order to solve the above technical problem, the present invention provides a crucible replacing apparatus, comprising: a base, a first mechanical arm and a second mechanical arm, wherein the first mechanical arm and the second mechanical arm are disposed on the base respectively, and perform the actions of turning, rising and falling along with the base; one end of the first mechanical arm is for catching the crucible to be replaced; and one end of the second mechanical arm is for carrying and placing the spare crucible.

According to an exemplary embodiment of the present invention, the angle between the first mechanical arm and the second mechanical arm is 90°.

According to an exemplary embodiment of the present invention, both the first mechanical arm and the second mechanical arm comprise: a rotational arm, a fixed arm and a driving unit; one end of the fixed arm is fixed on the base and the other end is hinged with the rotational arm; the rotational arm can rotate around a hinge point as driven by the driving unit, and one end of the rotational arm is provided with a clamping unit.

According to an exemplary embodiment of the present invention, the clamping unit comprises: at least two spring strips; one end of a spring strip is connected with the driving unit, and the other end is expandable outwardly after passing through a metal tube; the driving unit can drive the spring strips to stretch and retract in the metal tube; and the metal tube is vertically disposed at one end of the rotational arm.

According to an exemplary embodiment of the present invention, the base is provided with a lifting turntable thereon; and the first mechanical arm and the second mechanical arm are connected with the lifting turntable respectively.

According to an exemplary embodiment of the present invention, the crucible replacing apparatus further comprises a control unit connected with the driving unit and for sending an action command to the driving unit.

According to an exemplary embodiment of the present invention, the control unit is connected with a memory unit for recording the information of the position where the crucible is taken or placed.

According to an exemplary embodiment of the present invention, the driving unit is a motor or a pneumatic cylinder.

According to an exemplary embodiment of the present invention, the crucible replacing apparatus is disposed in an evaporation chamber.

The present invention also provides an evaporation system, comprising an evaporation chamber and the crucible replacing apparatus. The crucible replacing apparatus is disposed in the evaporation chamber; the evaporation chamber is provided with a plurality of evaporation sources therein; and at least one of the evaporation sources is provided with a crucible to be replaced.

According to an exemplary embodiment of the present invention, the evaporation source is of a point source type.

### (3) Beneficial Effects

The technical solution of the present invention has following beneficial effects: the present invention provides a crucible replacing apparatus, using the first mechanical arm to catch a crucible to be replaced, and then using the second mechanical arm to carry and place a spare crucible, thus achieving the replacement of the crucible in the evaporation source without opening the chamber and cooling to the room temperature.

### BRIEF DESCRIPTION OF THE DRAWINGS

FIG. 1 is a top view of the crucible replacing apparatus at the beginning of an action according to an embodiment of the present invention;

FIG. 2 is a top view of the first mechanical arm when it moves to above of the evaporation source according to an embodiment of the present invention;

FIG. 3 is a top view of the first mechanical arm when it takes away a crucible to be replaced according to an embodiment of the present invention;

FIG. 4 is a top view of the second mechanical arm when it moves to above the evaporation source according to an embodiment of the present invention;

FIG. 5 is a top view of the second mechanical arm after it places a spare crucible according to embodiment of the invention;

FIG. 6 is a side view of the crucible replacing apparatus before the spring strips are inserted into the air outlet of the crucible according to an embodiment of the present invention;

FIG. 7 is a side view of the crucible replacing apparatus after the spring strips are inserted into the air outlet of the crucible according to an embodiment of the present invention;

FIG. 8 is a structural schematic diagram of the base in a risen state according to the embodiment of the present invention;

FIG. 9 is a structural schematic diagram of the base in a fallen state according to the embodiment of the present invention.

### DETAILED DESCRIPTION OF SPECIFIC EMBODIMENTS

Implementation of the present invention will be further described in detail in conjunction with drawings and embodiments. The following embodiment are only used for illustrating the invention, rather than for limiting the scope thereof.

In the description of the present invention, it needs to be explained that unless otherwise mentioned, “a plurality of” means two or more; the terms “upper”, “lower”, “left”, “right”, “in”, “out”, “ front end”, “rear end”, “head portion”, “rear portion” and the like indicate orientation and position relationships based on the drawings, and are only used for facilitating and simplifying the description of the present invention, not indicating or implying that the indicated apparatus or element must have the particular orientation and be configured and operated in the particular orientation, and thus shall not be understood to limit the present invention. In addition, the terms “first”, “second”, “third” and the like are given by way of illustration only, and thus shall not be understood to indicate or imply any relative importance.

In the description of the present invention, it needs to be further explained that unless otherwise expressly stated and defined, the terms “install”, “connection” and “connect” should be understood in a broad sense. For example, they may be fixed connection, detachable connection, or integral connection; mechanical connection, or electrical connection; direct connection or indirect connection through an intermediate media. For those ordinary skilled in the art, the specific meanings of the above terms in the present invention may be understood according to specific circumstances.

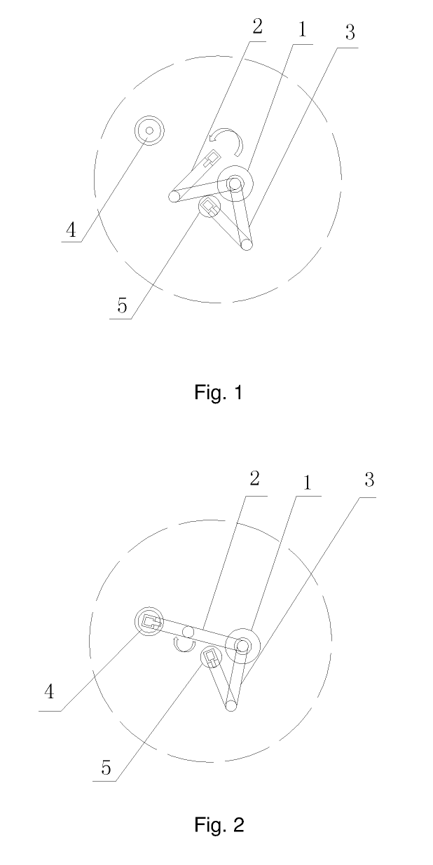

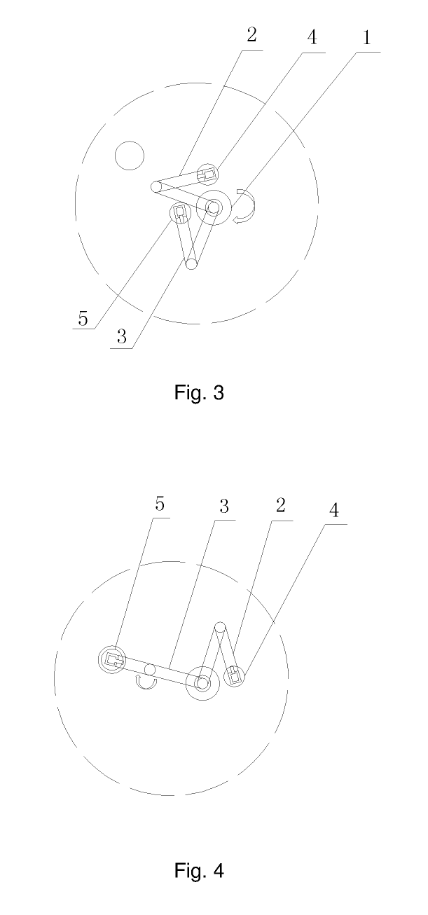

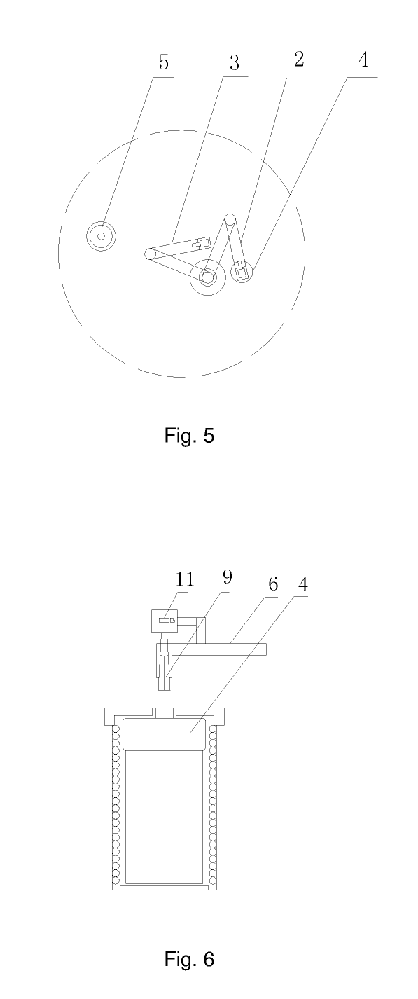

As shown in FIG. 1-5, an embodiment provides a crucible replacing apparatus, comprising: a base 1, a first mechanical arm 2 and a second mechanical arm 3; the first mechanical arm 2 and the second mechanical arm 3 are disposed on the base 1 respectively, and perform the actions of turning, rising and falling along with the base 1. In other words, the base 1 can not only rotate but also move up and down to carry the two mechanical arms to move along with it. The shapes and structures of the first mechanical arm 2 and the second mechanical arm 3 are not defined, but can be designed flexibly according to practical requirements, wherein one end of the first mechanical arm 2 is used for catching a crucible to be replaced 4, and one end of the second mechanical arm 3 is used for carrying and placing a spare crucible 5 (a crucible prepared in advance), thus achieving the replacement of the crucible (the crucible to be replaced 4) in the evaporation source without opening the chamber and cooling to the room temperature.

The specific operation process is as follows: firstly determining the crucible corresponding to the material with the largest consumption to be the crucible to be replaced 4, and installing a spare crucible 5 pre-filled with the material on the second mechanical arm 3; when the material of the crucible to be replaced 4 in the evaporation source is exhausted, starting the first mechanical arm 2 to take out the crucible to be replaced 4, and then using the second mechanical arm 3 to place the spare crucible 5 into the evaporation source. In this way, the addition amount of the material with the largest consumption is increased, thus prolonging the length of time of the evaporation in one time and reducing the number of times of opening the chamber; moreover, when replacing the crucible, the spare crucible 5 can be placed into the evaporation source without opening the chamber, as long as the temperature of the evaporation source is reduced to the preheating temperature, the whole process being less than 30 minutes.

According to an exemplary embodiment of the present invention, the angle between the first mechanical arm 2 and the second mechanical arm 3 is 90°. That is, the first mechanical arm 2 and the second mechanical arm 3 are disposed on the base 1 and arranged in a 90° central angle relative to each other on the base 1, such that the two mechanical arms will not interfere with each other when replacing the crucible, thus facilitating their cooperation and coordination.

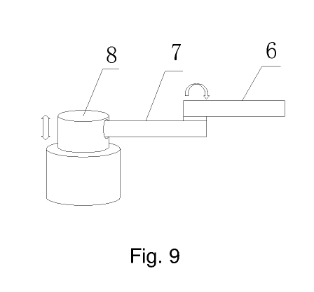

According to an exemplary embodiment of the present invention, as shown in FIG. 8-9, the first mechanical arm 2 and the second mechanical arm 3 have the same structure, and both the first mechanical arm 2 and the second mechanical arm 3 comprise: a rotational arm 6, a fixed arm 7 and a driving unit 11; one end of the fixed arm 7 is fixed on the base 1, and the other end is hinged with the rotational arm 6 (of course, the fixed arms 7 of the two mechanical arms maintain 90° all the time); the rotational arm 6 can turn left or right around the hinge point as driven by the driving unit. In addition, one end of the rotational arm 6 is provided with a clamping unit which facilitates taking and placing of the crucibles (the crucible to be replaced 4 and the spare crucible 5).

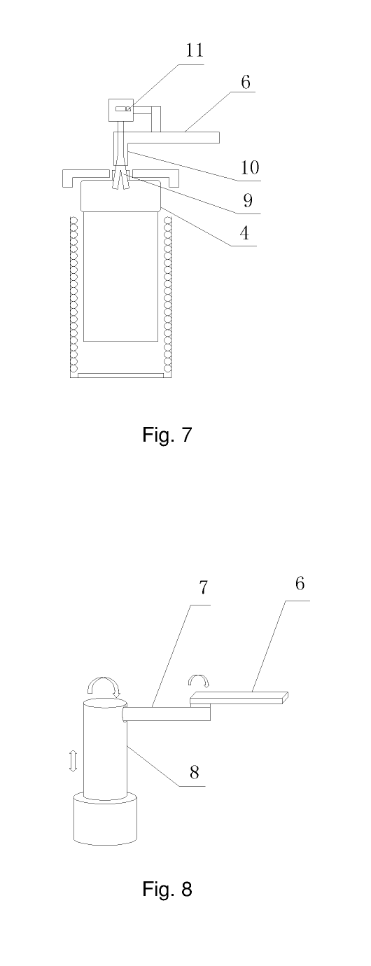

As shown in FIG. 6-7, the clamping unit comprises: at least two spring strips 9. Each spring strip is springy, and is expandable outwardly; preferably, the number of the spring strips is two.

According to an exemplary embodiment of the present invention, one end of the spring strips 9 are connected with the driving unit 11, and the other end are expandable outwardly after passing through a metal tube 10; and the driving unit 11 can drive the spring strips 9 to stretch and retract in the metal tube 10; the metal tube 10 is vertically disposed at one end of the rotational arm 6. It should be understood that each spring strip is springy, and may retract into the tube. When not retracting into the tube, the spring strips expand outwardly to form an angle therebetween; and when retracting into the tube under an upward pull of the driving unit 11, the angle between the spring strips disappears. The change of the angle causes the actions of clamping up and placing down the crucible. When in use, the spring strips 9 are retracted into the metal tube 10 as much as possible, making the lower ends thereof insertable into the air outlet of the crucible; then the driving unit 11 drives the spring strips 9 to stretch and retract in the metal tube 10, making the lower ends to be expanded outwardly after stretching out of the metal tube 10, thus clamping the air outlet of the crucible.

The form of the base 1 may also be various, and one form thereof is used for illustration: the base 1 is provided with a lifting turntable 8. The lifting turntable 8 is cylindrical, and may be understood as a lifting shaft with the functions of moving up and down and turning in the circumferential direction. Correspondingly, the first mechanical arm 2 and the second mechanical arm 3 are connected with the lifting turntable respectively.

The crucible replacing apparatus may further comprise a control unit. The control unit is connected with the driving unit 11, and is used for sending an action command to the driving unit 11, thus controlling the start-up of the driving unit 11, and facilitating the calibration of the position. The control unit is also connected with a memory unit which records the information of the position where the crucible is taken or placed. When in calibration, the control unit may generate coordinate values and record them in the memory unit. During a subsequent operation, the system may invoke the coordinate values generated during the calibration and move into place directly.

According to an exemplary embodiment of the present invention, the driving unit 11 is a motor or a pneumatic cylinder. It deserves to be explained that the driving unit 11 in the embodiment is a power source for providing power to each component, and the form thereof may be adjusted flexibly according to practical requirements. For example, the form of a motor plus a gear set or the form of a pneumatic cylinder plus a gear set may be adopted. Specially, the motor may be fixed on the rotational arm 6 through a bracket, and the output end thereof may be connected with the spring strips through the gear set to drive the spring strips 9 to stretch and retract in the metal tube 10. Of course, the motor may also drive the rotational arm 6 to rotate through the gear set. Obviously, the driving unit 11 is only a generic term for the convenience of description, and may comprise a plurality of subcomponents such as a motor, a gear set and the like.

In addition, the present invention also provides an evaporation system, comprising an evaporation chamber and the crucible replacing apparatus in the above embodiments. The crucible replacing apparatus is disposed in the evaporation chamber; the evaporation chamber is provided with a plurality of evaporation sources therein; and at least one evaporation source is provided with a crucible to be replaced 4 therein. The crucible replacing apparatus achieves the replacement of the crucible (the crucible to be replaced 4) in the evaporation source without opening the chamber and cooling to the room temperature.

According to an exemplary embodiment of the present invention, the evaporation source is a point source type evaporation source which is suitable for a point-source evaporator.

To sum up, the present invention provides a crucible replacing apparatus; a first mechanical arm is used to catch the crucible to be replaced, and then a second mechanical arm is used to carry and place the spare crucible, thus achieving the replacement of the crucible in the evaporation source without opening the chamber and cooling to the room temperature.

Embodiments of the present invention are given for illustration and description only, and are not exhaustive or used to limit the present invention to the disclosed form. For those of ordinary skill in the art, many modifications and variations are obvious. The selection and description of the embodiments are used for better illustrating the principle and practical application of the present invention as well as making those of ordinary skill in the art understand the present invention so as to be able to design various embodiments with various modifications for specific uses.

1. A crucible replacing apparatus, comprising: a base, a first mechanical arm and a second mechanical arm, wherein the first mechanical arm and the second mechanical arm are disposed on the base respectively, and perform the actions of turning, rising and falling along with the base; one end of the first mechanical arm is for catching a crucible to be replaced; and one end of the second mechanical arm is for carrying and placing a spare crucible.

2. The crucible replacing apparatus according to claim 1, wherein the angle between the first mechanical arm and the second mechanical arm is 90°.

3. The crucible replacing apparatus according to claim 1, wherein both the first mechanical arm and the second mechanical arm comprise: a rotational arm, a fixed arm and a driving unit; one end of the fixed arm is fixed on the base and the other end is hinged with the rotational arm; the rotational arm can rotate around the hinge point as driven by the driving unit, and one end of the rotational arm is provided with a clamping unit.

4. The crucible replacing apparatus according to claim 3, wherein the clamping unit comprises: at least two spring strips; one end of a spring strip is connected with the driving unit, and the other end is expandable outwardly after passing through a metal tube; the driving unit can drive the spring strips to stretch and retract in the metal tube; and the metal tube is vertically disposed at one end of the rotational arm.

5. The crucible replacing apparatus according to claim 1, wherein the base is provided with a lifting turntable thereon; and the first mechanical arm and the second mechanical arm are connected with the lifting turntable respectively.

6. The crucible replacing apparatus according to claim 3, further comprising a control unit connected with the driving unit and for sending an action command to the driving unit.

7. The crucible replacing apparatus according to claim 6, wherein the control unit is connected with a memory unit for recording the information of the position where a crucible is taken or placed.

8. The crucible replacing apparatus according to claim 6, wherein the driving unit is a motor or a pneumatic cylinder.

9. The crucible replacing apparatus according to claim 1, wherein the crucible replacing apparatus is disposed in an evaporation chamber.

10. An evaporation system, comprising an evaporation chamber and the crucible replacing apparatus according to claim 1, wherein the crucible replacing apparatus is disposed in the evaporation chamber; the evaporation chamber is provided with a plurality of evaporation sources therein, and at least one of the evaporation sources is provided with a crucible to be replaced therein.

11. The crucible replacing apparatus according to claim 10, wherein the evaporation sources are of a point source type.

12. The crucible replacing apparatus according to claim 10, wherein the angle between the first mechanical arm and the second mechanical arm is 90°.

13. The crucible replacing apparatus according to claim 10, wherein both the first mechanical arm and the second mechanical arm comprise: a rotational arm, a fixed arm and a driving unit; one end of the fixed arm is fixed on the base and the other end is hinged with the rotational arm; the rotational arm can rotate around the hinge point as driven by the driving unit, and one end of the rotational arm is provided with a clamping unit.

14. The crucible replacing apparatus according to claim 13, wherein the clamping unit comprises: at least two spring strips; one end of a spring strip is connected with the driving unit, and the other end is expandable outwardly after passing through a metal tube; the driving unit can drive the spring strips to stretch and retract in the metal tube; and the metal tube is vertically disposed at one end of the rotational arm.

15. The crucible replacing apparatus according to claim 10, wherein the base is provided with a lifting turntable thereon; and the first mechanical arm and the second mechanical arm are connected with the lifting turntable respectively.

16. The crucible replacing apparatus according to claim 13, further comprising a control unit connected with the driving unit and for sending an action command to the driving unit.

17. The crucible replacing apparatus according to claim 16, wherein the control unit is connected with a memory unit for recording the information of the position where a crucible is taken or placed.

18. The crucible replacing apparatus according to claim 16, wherein the driving unit is a motor or a pneumatic cylinder.

19. The crucible replacing apparatus according to claim 10, wherein the crucible replacing apparatus is disposed in an evaporation chamber.
